(19) United States
(12) Patent Application Publication
(10) Pub. No.: US 2015/0162361 A1
(43) Pub. Date: Jun. 11, 2015

(54) ARRAY SUBSTRATE, METHOD FOR FABRICATING THE SAME AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventor: Sheng Wang, Beijing (CN)

(21) Appl. No.: 14/354,247

(22) PCT Filed: Dec. 9, 2013
(86) PCT No.: PCT/CN2013/088840

§ 371 Date: Apr. 25, 2014

(30) Foreign Application Priority Data
Sep. 26, 2013 (CN) 201310446288.0

(51) Int. Cl. H01L 27/12

(52) U.S. Cl. CPC H01L 27/1244; H01L 27/1225; H01L 27/127; H01L 27/1288

(57) ABSTRACT

A display device, an array substrate and a method for fabricating the same are disclosed. The array substrate includes an oxide active layer; the oxide active layer includes a non-metallized semiconductor region and a metallized metal oxide conductor region.

### FIELD OF THE ART

Embodiments of the disclosure relate to the field of display technologies, more particularly, to an array substrate, a method for fabricating the same and a display device.

### BACKGROUND

Liquid Crystal Displays (LCDs) as important flat-panel display device have evolved rapidly during the past decade. Having the advantages of being lightweight, thin and power saving, LCD are widely used in modern information devices such as televisions, computers, mobile phones, digital cameras and the like. Recently, oxide Thin Film Transistors (TFTs) attract much attention from the industry due to high mobility. Oxide can reduce the size of the TFT and increase the resolution for having a higher mobility. However, increase in the resolution has to be accompanied by decreasing in the width of the source/drain electrode line, which will result in wire breakage occurring in metal lines.

### SUMMARY

Embodiments of the disclosure provide an array substrate, a method for fabricating the same and a display device.

An aspect of the disclosure provides an array substrate, comprising an oxide active layer; the oxide active layer comprises a non-metallized semiconductor region and a metallized metal oxide conductor region.

As an example, the array substrate further comprises an etch stop layer and a source/drain electrode layer,

the non-metallized semiconductor region corresponds to a location of the etch stop layer;

the metallized metal oxide conductor region corresponds to a location of the source/drain electrode layer.

As an example, the array substrate further comprises a gate electrode, a gate insulation layer, a pixel electrode layer and a passivation layer.

As an example, the oxide active layer is made of at least one of InGaZnO, InGaO, ITZO, AlZnO.

In another aspect, the disclosure further provides a method for fabricating an array substrate, comprising:

forming a pattern of an oxide active layer, the pattern of the oxide active layer comprising a non-metallized semiconductor region and a metallized metal oxide conductor region.

As an example, Ruining the pattern of the oxide active layer comprises:

forming an oxide semiconductor material;

forming a pattern of an etch stop layer on the oxide semiconductor material;

metallizing a portion of the oxide semiconductor material uncovered by the etch stop layer, and forming the non-metallized semiconductor region in a portion covered by the etch stop layer;

forming a source/drain metal layer, and foci ling a pattern of a source/drain electrode and the metal oxide conductor region at the same time through a patterning process.

As an example, the oxide active layer comprises at least one of InGaZnO, InGaO, ITZO, AlZnO.

As an example, the metallization is performed for 30 minutes to 120 minutes in a reducing atmosphere at a temperature of 100° C. to 300° C.

As an example, the reducing atmosphere comprises hydrogen or hydrogen-containing plasma.

As an example, the metallized metal oxide conductor region corresponds to a location of the source/drain electrode layer, the non-metallized semiconductor region corresponds to a location of the etch stop layer.

In another aspect, the disclosure further provides a display device comprising the above array substrate.

### BRIEF DESCRIPTION OF THE DRAWINGS

In order to clearly illustrate the technical solution of the embodiments of the disclosure, the drawings of the embodiments will be briefly described in the following. It is obvious that the described drawings are only related to some embodiments of the disclosure and thus are not limitative of the disclosure.

FIG. 1 schematically illustrates a configuration plan view of an array substrate in accordance with an embodiment of the disclosure;

FIG. 2 schematically illustrates a cross section view after finishing a gate electrode in an array substrate in accordance with an embodiment of the disclosure;

FIG. 3 schematically illustrates a cross section view after finishing fabricating an etch stop layer in an array substrate in accordance with an embodiment of the disclosure;

FIG. 4 schematically illustrates a cross section view after finishing fabricating a data line layer in an array substrate in accordance with an embodiment of the disclosure;

FIG. 5 schematically illustrates a cross section view after finishing a via hole process in an array substrate in accordance with an embodiment of the disclosure;

FIG. 6 schematically illustrates a cross section view of the whole array substrate after finishing a pixel electrode process in the array substrate in accordance with an embodiment of the disclosure;

FIG. 7 is a flow chart of a method for fabricating an array substrate in accordance with an embodiment of the disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

### Embodiment 1

The embodiment of the disclosure provides an array substrate; the array substrate will be described by taking a bottom-gate configuration as an example.

As illustrated in FIGS. 1 and 6, the array substrate comprises a substrate 0, disposed on the substrate 0 are a gate electrode 11, a gate insulation layer 21, an oxide active layer, an etch stop layer 23, a source/drain electrode layer 31, a passivation layer 41 and a pixel electrode layer 51; a via hole 42 is disposed in the passivation layer 41, the pixel electrode layer 51 is connected to the drain electrode by way of the via hole 42.

The oxide active layer comprises a semiconductor region 22 not being metallized and a metal oxide conductor region 24 being metalized.

As an example, the semiconductor region 22 corresponds to a location of the etch stop layer 23; the metal oxide conductor region 24 corresponds to a location of the source/drain electrode layer 31 and is disposed under the source/drain electrode layer 31.

The oxide active layer is made of for example at least one of InGaZnO, InGaO, ITZO, AlZnO. It can be contemplated that the material of the oxide active layer may also be, other than those above-described, other materials having the same or similar properties to the above materials.

According to the embodiment of the disclosure, the metal oxide conductor region is formed by metallizing the portion of the oxide active layer corresponding to the source/drain electrode layer. Since the metal oxide conductor region is of conductor properties, it can effectively decrease the resistance of the source/drain electrode layer and reduce the possibility of wire breakage occurring in the data line to the maximum extent.

### Embodiment 2

The embodiment of the disclosure provides an array substrate; the array substrate differs from that of Embodiment 1 in that the array substrate has a top-gate configuration.

The array substrate comprises a substrate, disposed on the substrate are a pixel electrode layer, a source/drain electrode layer, an oxide active layer, an etch stop layer, a gate insulation layer and a gate electrode, wherein the pixel electrode layer is connected to the drain electrode.

Herein the oxide active layer comprises a semiconductor region not being metallized and a metal oxide conductor region being metalized.

As an example, the semiconductor region corresponds to a location of the etch stop layer; the metal oxide conductor region corresponds to a location of the source/drain electrode layer and is disposed above the source/drain electrode layer.

The oxide active layer is made of for example at least one of InGaZnO, InGaO, ITZO, AlZnO. It can be contemplated that the material of the oxide active layer may also be, other than those above-described, other materials having the same or similar properties to the above materials.

It is noted that an improvement in the array substrate of the embodiment is mainly the improvement to the oxide active layer. For other layer structures please refer to conventional top-gate configurations, which will not be elaborated here.

### Embodiment 3

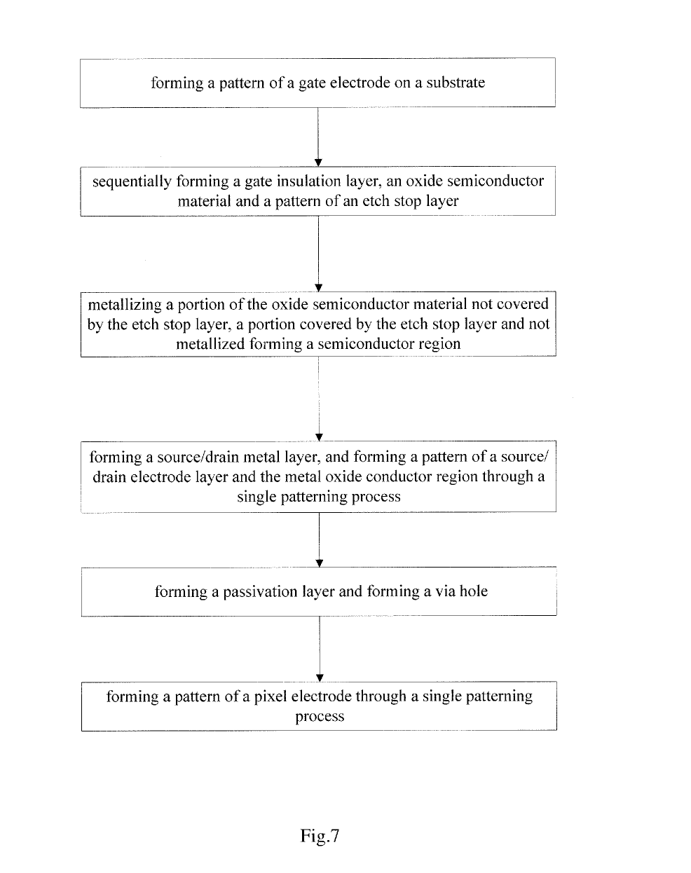

As illustrated in FIG. 7, based on the configuration of the array substrate of Embodiment 1, the disclosure further provides a method for fabricating an array substrate, comprising:

Step 1: forming a pattern of a gate electrode on a substrate.

For example, with reference to FIG. 2, a gate metal film is deposited on a substrate 0, the pattern of the gate electrode 11 is formed through a patterning process. The patterning process comprises for example exposing, developing, etching, peeling and the like; it may also be a printing or a screen printing process.

Step 2: sequentially forming a gate insulation layer, an oxide semiconductor material and a pattern of an etch stop layer.

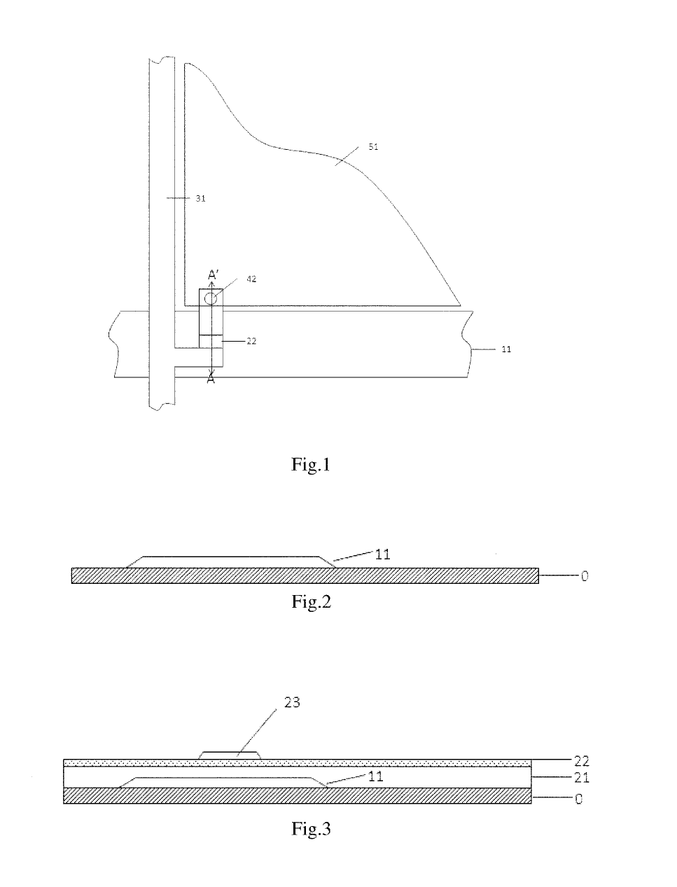

For example, with reference to FIG. 3, a gate insulation material, an oxide semiconductor material 22 and an etch stop layer material are deposited on the substrate done with step 1, and then the pattern of the etch stop layer 23 is formed through a patterning process.

The oxide semiconductor material may comprise for example at least one of InGaZnO, InGaO, ITZO, AlZnO. It can be contemplated that the material of the oxide semiconductor material may also be, other than those above-described, other materials having the same or similar properties to the above materials.

Step 3: metallizing a portion of the oxide semiconductor material not covered by the etch stop layer, a portion covered by the etch stop layer and not metallized forming a semiconductor region.

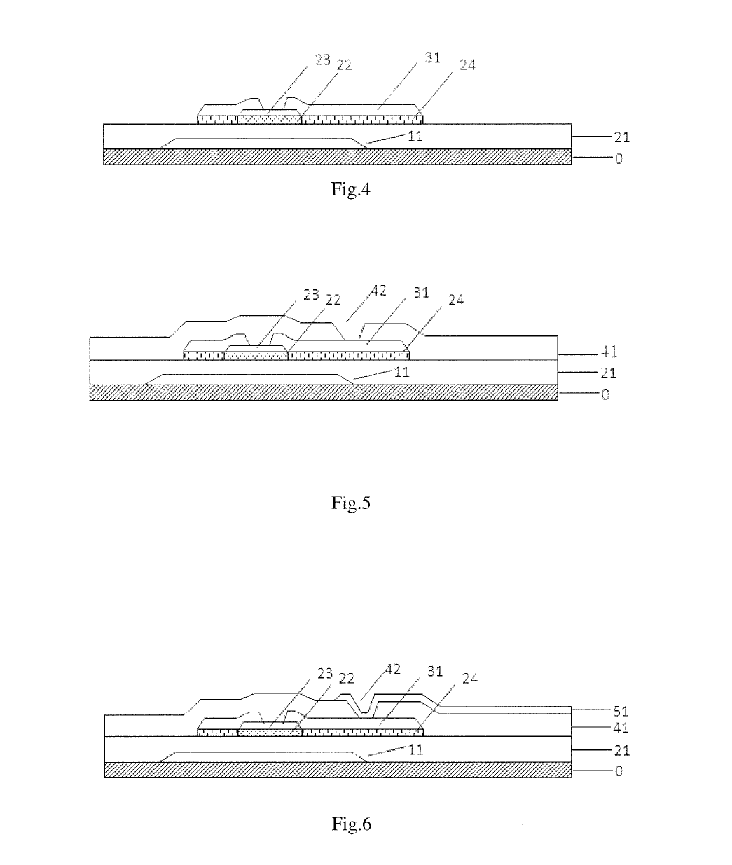

For example, with reference to FIG. 4, in the step, a portion of the oxide semiconductor material not covered by the etch stop layer is metallized. The metallization is performed for 30 minutes to 120 minutes in a reducing atmosphere at a temperature of 100° C. to 300° C.; the reducing atmosphere comprises hydrogen or hydrogen-containing plasma. By conducting the reduction reaction for 30 minutes to 120 minutes in the reducing atmosphere at a temperature of 100° C. to 300° C., it may maximally guarantee that the portion of the oxide active layer not covered by the etch stop layer is sufficiently and efficiently reduced to metal oxide conductor. If the temperature is too low, the effect of the reduction reaction will be compromised and the reaction time will be prolonged, which will decrease the production efficiency. If the temperature is too high, the portion of the oxide active layer covered by the etch stop layer and not requiring metallization will suffer chemical reaction and have its structure affected. Similarly, if the reaction time is too short, the reduction reaction will not be sufficiently conducted; if the time is too long, it will extend the reaction time and reduce the production efficiency.

The metallized metal oxide conductor region has the properties of conductors; therefore, it can effectively decrease the resistance of the source/drain electrode layer and reduce the possibility of wire breakage occurring in the source/drain electrode layer to the maximum extent.

The portion of the oxide semiconductor material covered by the etch stop layer is the semiconductor region 22.

Step 4: forming a source/drain metal layer, and forming a pattern of a source/drain electrode layer and the metal oxide conductor region through a single patterning process.

Still referring to FIG. 4, to save producing steps, the pattern of the source/drain electrode 31 and the pattern of the metal oxide conductor region 24 are formed in a same and one patterning process. Herein the metal oxide conductor region 24 corresponds to a location of the source/drain electrode layer 31 and is disposed under the source/drain electrode layer 31.

For example, the step comprises: depositing a source/drain metal layer on the metallized metal oxide conductor region 24, after exposing these two film layers with a single exposing process, first etching the source/drain metal layer once to form the pattern of the source/drain electrode layer, then continuing etching the metal oxide conductor region by changing the etchant to form the pattern of the metal oxide conductor region. The source/drain electrode layer and the metal oxide conductor region may be the same or different from each other.

Step 5: forming a passivation layer and forming a via hole.

With reference to FIG. 5, a passivation layer 41 and a via hole 42 are formed on the substrate done with the previous step with a patterning process.

Step 6: forming a pattern of a pixel electrode through a patterning process.

With reference to FIG. 6, a pattern of a pixel electrode 51 is formed on the substrate done with the previous step with a patterning process.

According to the embodiment of the disclosure, the metal oxide conductor region is formed by metallizing the portion of the oxide active layer not covered by the etch stop layer. Since the metal oxide conductor region is of conductor properties, it can effectively decrease the resistance of the source/drain electrode layer and reduce the possibility of wire breakage occurring in the data line.

It is noted that the patterning processes used in the disclosure are processes such as exposing, developing, etching, and peeling generally used in conventional art.

Furthermore, an embodiment of the disclosure provides a display device comprising the above array substrate. The display device may be a liquid crystal panel, an E-paper, an OLED panel, a liquid crystal television, a liquid crystal display, a digital photo-frame, a mobile phone, a tablet PC and any product or component having a display function.

What are described above is related to the illustrative embodiments of the disclosure only and not limitative to the scope of the disclosure; the scopes of the disclosure are defined by the accompanying claims.

1. An array substrate, comprising an oxide active layer, wherein
the oxide active layer comprises a non-metallized semiconductor region and a metallized metal oxide conductor region.

2. The array substrate of claim 1, wherein the array substrate further comprises an etch stop layer and a source/drain electrode layer,
the non-metallized semiconductor region corresponds to a location of the etch stop layer;
the metallized metal oxide conductor region corresponds to a location of the source/drain electrode layer.

3. The array substrate of claim 1, wherein the array substrate further comprises a gate electrode, a gate insulation layer, a pixel electrode layer and a passivation layer.

4. The array substrate of claim 1, wherein the oxide active layer is made of at least one of InGaZnO, InGaO, ITZO, AlZnO.

5. A method for fabricating an array substrate, comprising:
forming a pattern of an oxide active layer, the pattern of the oxide active layer comprising a non-metallized semiconductor region and a metallized metal oxide conductor region.

6. The method of claim 5, wherein forming the pattern of the oxide active layer comprises:
forming an oxide semiconductor material;
forming a-pattern of an etch stop layer on the oxide semiconductor material;
metallizing a portion of the oxide semiconductor material uncovered by the etch stop layer, and forming the non-metallized semiconductor region in a portion covered by the etch stop layer;
forming a source/drain metal layer, and forming a pattern of a source/drain electrode and the metal oxide conductor region at the same time through a patterning process.

7. The method of claim 6, wherein the oxide semiconductor material comprises at least one of lnGaZnO, InGaO, ITZO, AlZnO.

8. The method of claim 5, wherein the metallization is performed for 30 minutes to 120 minutes in a reducing atmosphere at a temperature of 100° C. to 300° C.

9. The method of claim 8, wherein the reducing atmosphere comprises hydrogen or hydrogen-containing plasma.

10. The method of claim 6, wherein the metallized metal oxide conductor region corresponds to a location of the source/drain electrode, the non-metallized semiconductor region corresponds to a location of the etch stop layer.

11. A display device, comprising the array substrate of claim 1.

12. The array substrate of claim 2, wherein the array substrate further comprises a gate electrode, a gate insulation layer, a pixel electrode layer and a passivation layer.

13. The array substrate of claim 2, wherein the oxide active layer is made of at least one of InGaZnO, InGaO, ITZO, AlZnO.

14. The array substrate of claim 3, wherein the oxide active layer is made of at least one of lnGaZnO, InGaO, ITZO, AlZnO.

15. The method of claim 6, wherein the metallization is performed for 30 minutes to 120 minutes in a reducing atmosphere at a temperature of 100° C. to 300° C.

16. The method of claim 7, wherein the metallization is performed for 30 minutes to 120 minutes in a reducing atmosphere at a temperature of 100° C. to 300° C.

17. The display device of claim 11, wherein the array substrate further comprises an etch stop layer and a source/drain electrode layer,
the non-metallized semiconductor region corresponds to a location of the etch stop layer;
the metallized metal oxide conductor region corresponds to a location of the source/drain electrode layer.

18. The display device of claim 11, wherein the array substrate further comprises a gate electrode, a gate insulation layer, a pixel electrode layer and a passivation layer.

19. The display device of claim 17, wherein the array substrate further comprises a gate electrode, a gate insulation layer, a pixel electrode layer and a passivation layer.

20. The display device of claim 11, wherein the oxide active layer is made of at least one of InGaZnO, InGaO, ITZO, AlZnO.
